(19) United States
(12) Patent Application Publication
(10) Pub. No.: US 2022/0377877 A1
(43) Pub. Date: Nov. 24, 2022

(54) PRINTED CIRCUIT BOARD AND FLUID HEATER

(71) Applicant: DBK David + Baader GmbH, Rülzheim (DE)

(72) Inventors: Sebastian SCHÖNEICH, Rülzheim (DE); Alexander KRÄMER, Kapsweyer (DE); Simon FISCHER, Karlsruhe (DE)

(73) Assignee: DBK David + Baader GmbH, Rülzheim (DE)

(21) Appl. No.: 17/761,286

(22) PCT Filed: Sep. 15, 2020
(86) PCT No.: PCT/EP2020/075772

§ 371 Date: Mar. 17, 2022

(30) Foreign Application Priority Data
Sep. 19, 2019 (DE) 10 2019 214 314.8
Dec. 4, 2019 (DE) 10 2019 133 043.2

(51) Int. Cl. H05K 1/02; H05B 3/26

(52) U.S. Cl. CPC H05K 1/0212; H05B 3/262

(57) ABSTRACT

A printed circuit board includes a conducting path shaped via a subtractive method and a heating line. The heating line is formed by the conducting path and designed to have a predetermined heating power for a heating fluid. The printed circuit board further includes a heat dispersion layer designed for transferring heat to the fluid. A heater includes such a printed circuit board.

### CROSS REFERENCE TO RELATED APPLICATIONS

This application is a US National Phase of International Application Number PCT/EP2020/075772, filed Sep. 15, 2020, claiming priority to DE102019214314.8, filed Sep. 19, 2019, and DE102019133043.2, filed Dec. 4, 2019, the contents of which are incorporated into the subject matter of the present application by reference.

### BACKGROUND

The application relates to a printed circuit board according to the preamble of claim 1 and to a fluid heater configured with such a printed circuit board.

Such fluid heaters are preferably used for heating gaseous or liquid media, for example air or water. The basic design of these fluid heaters is explained, for example, in document DE 10 2016 122 767 A1, which belongs to the Applicant. This fluid heater configured for heating air has a heating element configured as a tubular heating element, the heat of which is transferred to the fluid to be heated via a heat exchanger, also called a heat distribution element. In the fluid heater specifically described in DE 10 2016 122 767 A1, this heat distribution element is configured as a metal sponge or wire mesh/wire netting, wherein the fluid flows through the pores or conduits formed as a result. Of course, other heat distribution elements, for example extruded profiles or corrugated ribs, may also be used for heat exchange. The heating element is driven by control and power electronics, the circuitry of which is formed on a printed circuit board/conductor board, and which is arranged in an electronics housing attached to a housing accommodating the heating element and the heat distribution element. An inlet and an outlet for the fluid to be heated are also formed on this housing.

Document DE 10 2012 209 936 A1 describes a thick-film heater in which conducting paths are applied to a substrate by an additive process. These conducting paths form a heating resistor of a heating device.

In DE 10 2018 106 354 A1, also belonging to the Applicant, it is proposed to use power semiconductors arranged on the printed circuit board as heating elements, so that the heat generated during operation of the power semiconductors is transferred to the fluid to be heated via a heat distribution element.

The problem with this solution is that the heat generated by the power semiconductors is only generated at specific points in relation to the total heat exchange surface, so that considerable effort is required to enable areal heat transfer by designing the heat distribution element accordingly. In addition, the technical equipment required for this solution is considerable, since the interconnection of the power semiconductors used essentially for heating is complex compared with conventional solutions using tubular heating elements or PTC heating elements and is also expensive due to the comparatively high price of the semiconductors.

### SUMMARY

In contrast, the object of the application is to further develop the printed circuit board provided with a circuit forming a control or power electronics and a heater configured therewith in such a way that effective heating of a fluid is made possible with reduced effort, in particular reduced circuitry-related effort.

This object is solved with respect to the printed circuit board by the feature combination of an independent claim for a printed circuit board and with respect to the heater by the features of an independent claim for a heater.

Advantageous further developments of the application are the subject matter of the dependent claims.

The printed circuit board/conductor board according to the application is provided with at least one heating line configured for a predetermined heating power for heating a fluid. This heating line is formed by conducting paths shaped via a subtractive process, for example by etching, whose cross-section, length, and material are designed according to the heating resistance required for the heating power. The material is accordingly selected such that it can be machined via a subtractive process, for example by etching or milling.

According to the application, the printed circuit board/conductor board is thus initially formed with a continuous layer/coat of the conducting path material, from which the areas not forming a conducting path are then removed by etching or

A solution of this kind makes adapting to different heating powers possible in a simple manner by suitable selection of the cross-section and geometry of the heating line, wherein the circuitry-related effort is considerably reduced compared to the solution described at the beginning with power semiconductors specially configured for heating. According to the application, such power semiconductors are required at most for driving or respectively controlling the heating circuit. Thus, according to the application, the parasitic side effect resulting from the fact that the conducting-path portions are heated by energization is exploited when the conducting path is energized.

According to the application, the printed circuit board is configured with a heat dispersion layer for heat transfer to the fluid. This heat dispersion layer may be configured, for example, as a molded part that is integrated into the layer structure of the printed circuit board and is optimized with regard to fluid guidance and heat transfer. By integrating the heat dispersion layer into the printed circuit board/conductor board structure, the device-related effort is reduced compared to conventional solutions in which a separate heat distribution element, for example heat exchange surfaces or the like, have to be applied.

The printed circuit board is preferably designed as an IMS (Insulated Metal Substrate) conductor board, in which a heat dispersion layer is already conceptually integrated.

Another significant advantage of the solution according to the application is that the suitable surface extension of the heating lines/conducting paths ensures uniform heat distribution for heating the fluid.

In one configuration example of the application, in addition to the heating line, a control circuit and/or power electronics is formed on the printed circuit board/conductor board, which is configured, for example, for driving the heating line or other electronic components.

According to a preferred configuration example of the application, several heating lines are configured on the printed circuit board, which are individually drivable.

Each IMS printed circuit board may be configured in multiple layers with at least two functional layers, in each of which a heating element and/or the control circuit and/or power electronics may be configured. Accordingly, one layer of the IMS printed circuit board may be configured as a heating element and another layer may form a control circuit or power electronics. Of course, mixed forms are also possible, in which one layer is effective both as a heating element and in the sense of driving components. In principle, the IMS printed circuit board may also be configured as a single layer, wherein this layer fulfills the function of both a heating element and a control circuit/power electronics.

Heat transfer is further improved if at least sections of the heating line are configured as meander-shaped conducting paths. Alternatively, however, the conducting paths may also be connected in series and/or in parallel in a parallel arrangement or the like.

The manufacture of the printed circuit board and its connector elements is particularly simple if the latter and other functional elements are configured by bending tabs or edge portions of the IMS conductor board. For example, it is possible to lead a conducting-path terminal portion to such an edge portion and then to form a contact tab or the like by bending it.

Furthermore, it is possible that at least one heating line is configured in the bent portion, which is contacted via portions of the conducting path that are routed over the bent areas. It is also possible to have at least one heating line run in sections in the bent portion.

The heater according to the application has a heating element configured with a printed circuit board of the type described above.

The conducting path may be meander-shaped or bifilar.

It is particularly preferred if the printed circuit board bounds at least in sections a fluid conduit through which the fluid flows or a fluid compartment which accommodates the fluid. I.e., in such a variant, the printed circuit board forms part of the fluid conduit/fluid compartment. This concept, with a fluid compartment bounded in sections by the printed circuit board, is the subject matter of a parallel patent application filed by the Applicant.

### BRIEF DESCRIPTION OF THE DRAWINGS

Preferred configuration examples of the application are explained in more detail below with reference to schematic drawings. The following is shown:

FIG. 1 shows a three-dimensional representation of a first configuration example of a fluid heater according to the application.

FIG. 2 shows the fluid heater according to FIG. 1 with the lid removed.

FIG. 3 shows a schematic representation of an IMS conductor board of the fluid heater according to FIGS. 1 and 2.

FIG. 4 shows a detailed representation of the IMS conductor board according to FIG. 3.

FIG. 5 shows a schematic representation of the cross-section of such an IMS conductor board.

FIG. 6 shows a representation to illustrate the geometry of two heating lines of an IMS conductor board according to FIGS. 4 and 5.

FIG. 7 shows a section along line A-A in FIG. 1.

FIG. 8 shows a corresponding section of another configuration example of a fluid heater.

FIG. 9 shows an individual representation of a molded part for guiding fluid in a heater according to the application.

FIGS. 10a, 10b show highly schematized representations of configuration examples in which the printed circuit board according to the application forms connector elements and/or a fluid compartment by bending.

### DESCRIPTION

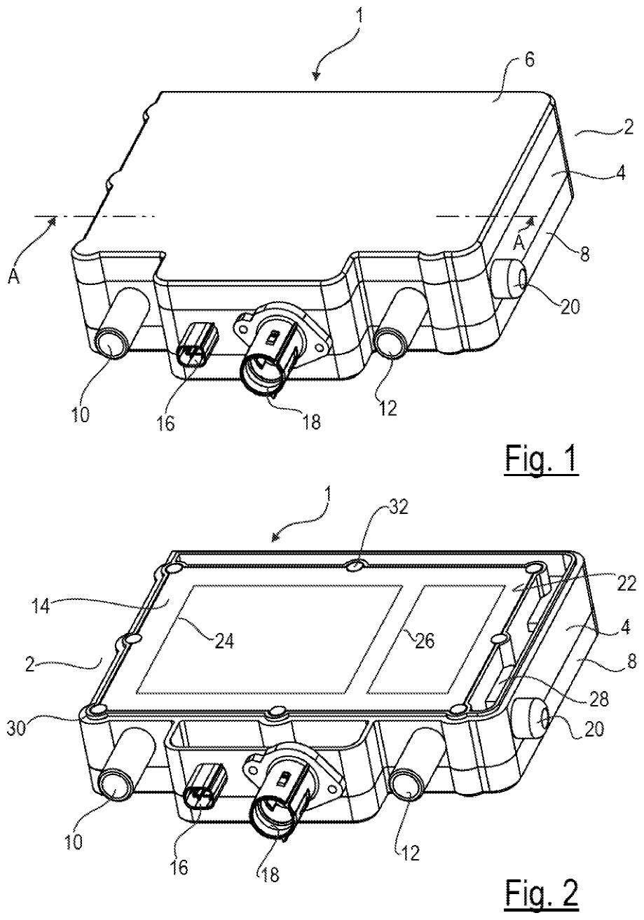

FIG. 1 shows a three-dimensional representation of a first configuration example of a fluid heater 1 according to the application, for example a high-voltage heater, which is used for heating water or another liquid, for example. The fluid heater 1 has a multi-part housing 2 with a center part 4 and, in the view according to FIG. 1, an upper and lower lid 6, 8. This housing 2 delimits a fluid compartment which holds the fluid to be heated and which will be discussed below. Two fluid connections 10, 12 open into this fluid compartment, wherein, for example, the fluid connection 10 may be configured as an inlet and fluid connection 12 as an outlet. Both connections 10, 12 are connected to a pipe system carrying the fluid to be heated. In the configuration example shown, the fluid connections 10, 12 are configured as connector nozzles on the center part 4. Of course, these connections may also be provided on the lid side.

The housing 2 according to the application also accommodates at least one printed circuit board 14 (see FIG. 2), which is configured with at least one heating circuit for heating the fluid and may have additional electronic components for driving this heating circuit and other heater components. For the power supply of these control and/or power electronics as well as of the electronic components, a low-voltage plug 16 and a high-voltage plug 18 are configured at the center part 4 in the configuration example shown in FIG. 1, wherein the latter serves for the high-voltage power supply and the low-voltage plug also serves for signal transmission. For compensation of pressure fluctuations occurring in an electronics compartment housing the control and power electronics during operation, a pressure-balancing element marked with reference sign 20 in FIG. 1 is provided. With regard to EMC problems, for example, the housing components may be made of suitably coated plastic or a suitable metal alloy.

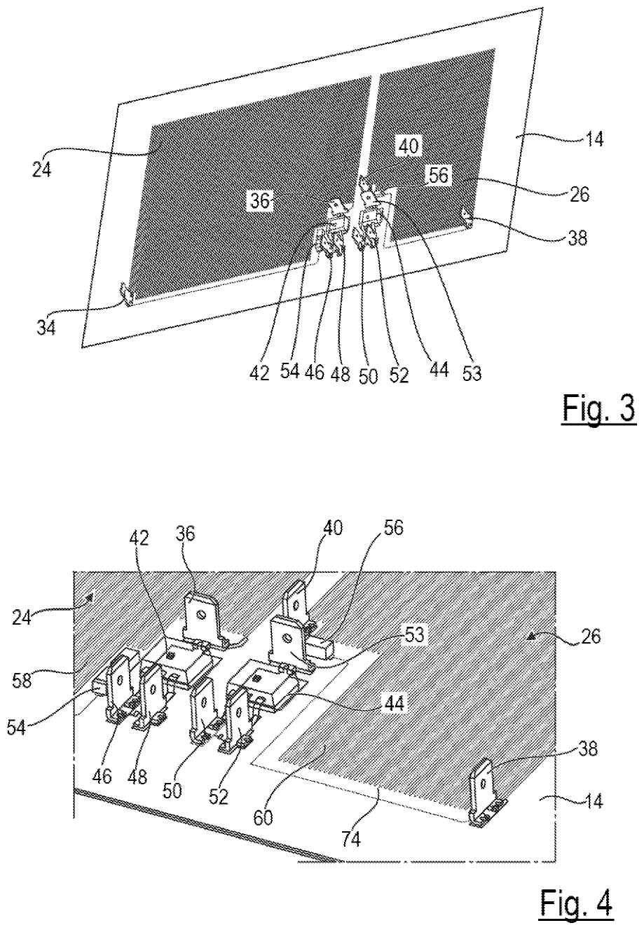

FIG. 2 shows the housing 2 according to FIG. 1, wherein the upper lid 6 is removed. The above-mentioned electronics compartment 22 can then be seen, in which the printed circuit board 14 is arranged, via which on the one hand control and/or power electronics may be formed and on the other hand the actual heating of the fluid heater 1 may be formed. In the configuration example shown, the printed circuit board 14 is formed with two heating circuits 24, 26, the specific structure of which will be explained later with reference to FIGS. 3 to 6. According to the representation in FIG. 2, the electronics compartment 22 does not fill the entire interior space of the housing 2, but is surrounded, for example, by an approximately L-shaped exterior space 28 in this configuration example, in which further components of the fluid heater, for example cabling, may be accommodated.

A clearance not visible in FIG. 2 remains between the removed upper lid 6 and the printed circuit board 14 as well as between the lower lid 8 and possibly a further printed circuit board or the printed circuit board 14, wherein in this clearance, for example, an additional control board or other components, such as a temperature sensor or the like, may be accommodated.

In a manner known per se, sealing contours 30 are formed on the end edges of the center part 4 visible in FIG. 2, which serve to fix the position of a seal. Corresponding contours are also formed on the upper lid 6 and the lower lid 8 so that the housing 2 can be closed in a fluid-tight manner. The center part 4 is clamped to the two lids 6, 8 via screws which are screwed into corresponding thread holes 32 of the center part 4. Of course, instead of such a screw connection, the housing 2 may also be connected by a material bond.

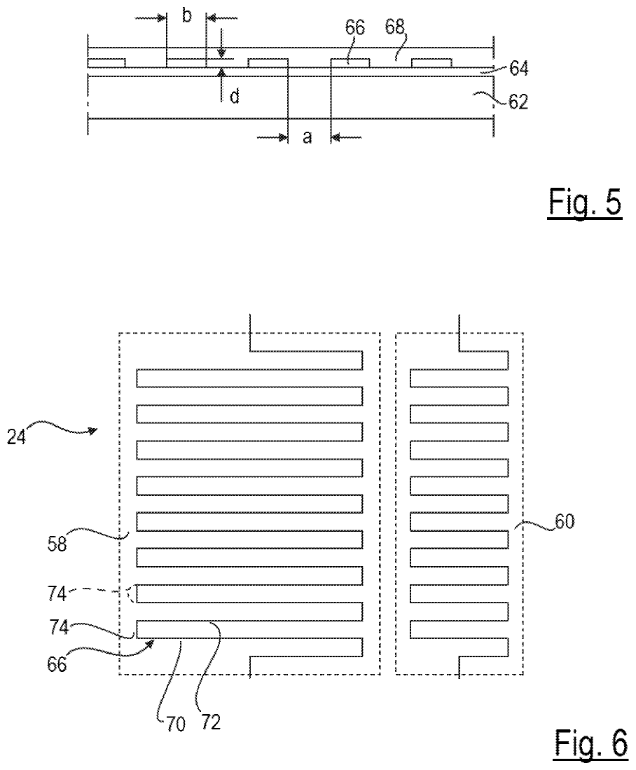

FIG. 3 shows an individual representation of the printed circuit board 14 accommodated in the housing 2. This is configured as an IMS printed circuit board—the basic structure of such IMS printed circuit boards 14 will be explained later with reference to FIG. 5.

In the configuration example shown (see also FIG. 4), the printed circuit board 14 is designed—as mentioned above—with the two heating circuits 24, 26, wherein the heating circuit 24 is configured for a heating power of, for example, 2 KW and the heating circuit 26 for a heating power of, for example, 1 KW. The voltage supply of the two heating circuits 24, 26 is provided via terminal lugs 34, 36 (heating circuit 24) or 38, 40 (heating circuit 26) protruding from the plane of the printed circuit board, wherein switching on and off of the heating lines described in more detail below is performed via switch elements 42, 44, which are configured, for example, as IGBT components and are part of the circuit formed by the printed circuit board 14. The connections of these switch elements 42, 44 are marked with the reference signs 46, 48, 50, 52, 53 in the illustration according to FIG. 3. Further electronic components 54, 56 of the control and/or power electronics are configured on the printed circuit board 14 according to FIG. 3. In principle, a sensor for detecting the fluid temperature can also be integrated into the circuit implemented by the printed circuit board 14.

The components described sit—as explained above—on the printed circuit board 14, so that their power dissipation is also transferred to the fluid in the form of heat. Such a solution, in which the electronic components, for example semiconductor components, are configured as heating elements, is explained in DE 10 2018 106 354 A1 described at the beginning. In contrast to this solution, heating lines of the two heating circuits 24, 26 formed by conducting paths are configured with respect to the heating power to be transmitted. As explained at the beginning, however, the printed circuit board according to the application is not limited to a configuration example in which the conducting paths are configured together with control elements and/or a power electronics—in principle, it is sufficient if only one heating line formed by at least one conducting path is configured on the printed circuit board 14, which is configured with regard to the heating of a fluid.

FIG. 4 shows a detailed view of the area of the printed circuit board 14 from FIG. 3 that is equipped with the above-mentioned electronic components. It can be seen quite clearly in this representation that in this configuration example the two heating circuits 24, 26—as mentioned above—are realized by heating lines 58, 60 formed from conducting paths, wherein the conducting paths are each formed in a meander-shape on the printed circuit board 14. This will be illustrated later using FIG. 6.

As mentioned above, the printed circuit board 14 is configured as an IMS printed circuit board. According to FIG. 5, this has a heat dispersion layer 62 in a manner known per se, which usually consists of a metal, for example aluminum or copper, and whose layer thickness may vary between 0.3 mm and 10 mm. A layer thickness of around 1.5 mm has become established as the standard.

On this heat dispersion layer 62, which is configured for optimum heat transfer to the fluid to be heated, an integrated insulating layer 64 is applied, which typically has a layer thickness of 75 μm to 200 μm and is made of a material with good electrical insulation properties, preferably plastic. The conducting path 66 forming the actual heating line 58, 60 is then applied to this insulating layer 64. The conducting path 66 consists of a material that can be processed by etching or milling, such as copper, zinc, silver, gold, or nickel, wherein copper is preferred.

As explained in DE 10 2018 106 354 A1, a conducting-path layer is first applied over the entire surface and then the meander-shaped or bifilar structure of the heating lines 58, 60 and the conducting-path portions leading to the aforementioned components/switch elements, which will be explained in more detail below, is produced by an etching process, resulting in the heating-line structure indicated in FIGS. 4 and 6.

For electrical insulation and moisture protection, an insulating layer, for example a layer of solder resist 68, may then be applied to this etched IMS conductor board 14 in a further work step, covering the conducting-path structure. Here, areas are left out on which the above-mentioned switch elements 42, 44 and electronic components 54, 56 are applied in a subsequent assembly operation—for example in an SMD process. After this equipping according to an equipping plan, the outer shape of the IMS printed circuit board 14 is formed in a fourth work step by punching, milling and/or sawing.

The structure of the heating lines 58, 60 is configured with regard to the desired heating power. The heating resistance of the two heating lines 58, 60 is essentially determined by the material, the length and the cross-section of the conducting paths 66, which are arranged, for example, in a meandering or bifilar manner. Accordingly, the conducting path width b and the layer thickness d of the conducting path 66 and their length are selected in such a way that the heating resistance required for the predetermined heating power is obtained. The heating resistance may also be changed locally by varying the cross-section (b, d). This local variation of the heating resistance can be used to deliberately generate hot spots that form a kind of fuse and melt in the event of excessive temperature development or current flow. Likewise, zones with fewer conducting paths, and thus lower power density, can be generated locally. The spacing a of the individual conducting paths 66 of the meander structure also has an influence on the power density.

FIG. 6 shows the basic structure of the heating circuit 24 designed with a greater heating power, which in principle consists of two heating lines 58a, 58b, which can be driven individually or jointly via the above-mentioned switch elements 42, 44 and electronic components 54, 56. As explained, each heating line 58a, 58b in this configuration example is formed by a meander-shaped conducting path 66, wherein longer conducting-path portions 70, 72 are connected to each other via redirections 74.

Of course, as mentioned above, other structures may be used instead of the meander-shaped structure, for example parallel conducting paths arranged in parallel or series, bifilar structures, or mixed forms of these structures. In the configuration example shown in FIG. 6, the redirections 74 are configured as straight elements extending transversely to the conducting-path portions 70, 72. In the configuration example shown in FIG. 4, the redirections 74 are rounded (see also dashed line in FIG. 6).

The individual heating line 60 of the second heating circuit 26 has a corresponding structure, wherein the heating power of the individual heating lines 58a, 58b and 60 in the illustrated configuration example is configured according to the desired maximum heating power.

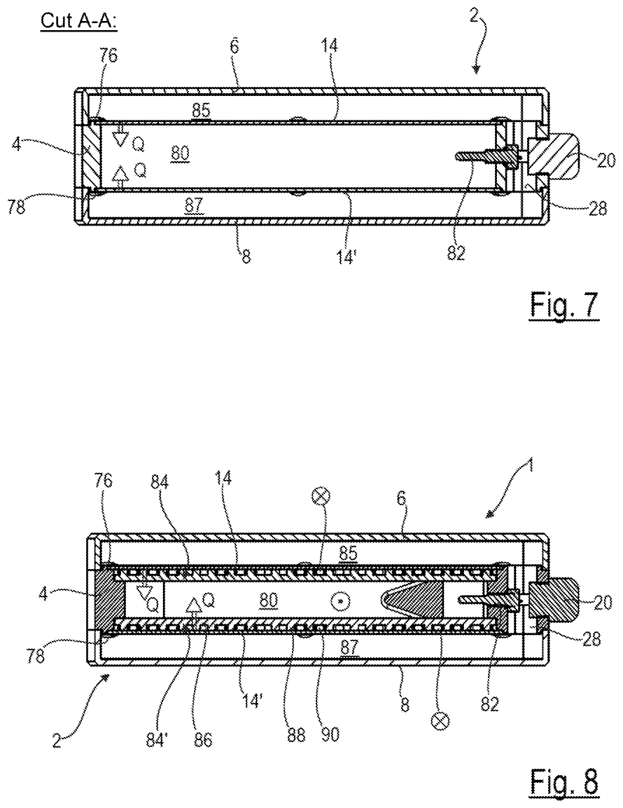

FIG. 7 shows a section along the line A-A in FIG. 1. In this sectional view, the circumferential walls of the center part 4 are visible, onto which the upper lid 6 and the lower lid 8 are placed in a sealed manner. In the configuration example shown, the center part 4 carries an IMS printed circuit board 14 configured as described above, which is configured with at least one heating circuit and can additionally carry components of the control and power electronics. This printed circuit board 14 is arranged in the area overlapped by the upper lid 6.

In the area overlapping the lower lid 8, a further printed circuit board 14′ is formed, which can be configured in accordance with the printed circuit board 14 with a heating circuit and/or other components of the control and/or power electronics. In principle, it is also possible to configure the printed circuit board 14 with several heating circuits as a ‘heating board’, while the additional printed circuit board 14′ accommodates the electronic components required for control and regulation, i.e., the components of the control and power electronics, so that each printed circuit board 14, 14′ is optimized with regard to the respective function (heating—control, regulation). The printed circuit boards 14, 14′ are held in a sealing manner on the center part 4 via suitable sealing elements 76, 78, so that a fluid compartment 80 is formed by the printed circuit boards 14, 14′ and the center part 4, through which the fluid to be heated flows or in which the fluid to be heated is accommodated. The printed circuit boards 14, 14′ according to the application thus directly bound the fluid compartment 80. This is a significant difference from the solution according to DE 10 2018 106 354 A1, in which the printed circuit board is applied to the circumferential walls of the fluid compartment, so that there is no direct heat input from the printed circuit board into the fluid.

In the configuration example shown in FIG. 7, the temperature sensor 82 mentioned at the beginning projects into the fluid compartment 80. The pressure-balancing element 20 can also be seen, which in the representation according to FIG. 7 is merely coaxial to the axis of the temperature sensor 82. As explained at the beginning, this optional pressure-balancing element 20 ensures that pressure fluctuations in the clearances 85, 87 arranged above or respectively below the fluid compartment 80, which form a type of electronics compartment, are compensated.

The printed circuit boards 14, 14′ are arranged in such a way that the heat dispersion layers 62 described above bound the fluid compartment in sections, while the electronic components and the heating lines 58a, 58b, 60 are arranged with the conducting paths 66 facing the two free spaces 85, 87. As mentioned above, further printed circuit boards or other elements of the control/power electronics not shown here can be arranged in these clearances 85, 87.

In the section according to FIG. 7, a part of the exterior space 28 explained in FIG. 2 can also be seen, in which, for example, cabling can be guided and which is connected to the two free spaces 85, 87. In the case where fluid flows through the fluid compartment 80, fluid guiding elements 84 may be provided in the area of the fluid compartment 80 (see FIG. 8).

In the configuration example shown in FIG. 7, the fluid compartment 80 is arranged centrally between the two printed circuit boards 14, 14′. In principle, it is also possible to mount the printed circuit boards rotated by 180° so that the heat dispersion layers 62 each face the upper lid 6 or the lower lid 8, respectively, and two fluid compartments are then bounded by the respective lid 6, 8, which are in fluid communication with each other. In such a variant, which is not shown, the components of the control or power electronics and also the heating lines 58a, 58b, 60 are then arranged facing the common central space between the printed circuit boards 14, 14′. Accordingly, the pressure-balancing element 20 would then have to be in operative connection with the central space, while the temperature sensor 82 would have to be arranged in at least one of the spaces bounded by the lids 6, 8.

FIG. 8 shows a variant of the configuration example according to FIG. 7, in which the two printed circuit boards 14, 14′ partially bound the central fluid compartment 80 and the two lids 6, 8 with the printed circuit boards 14, 14′ form a clearance 85, 87, respectively. In this respect, the configuration example according to FIG. 8 corresponds to that according to FIG. 7. In contrast to FIG. 7, in the configuration example according to FIG. 8, a fluid guiding element 84, 84′ is attached to each of the heat dispersion layers of the printed circuit boards 14, 14′ facing the fluid compartment 80, which on the one hand improves the heat transfer from the aforementioned heating lines 58a, 58b to the fluid, and on the other hand serves to guide the flow. In the configuration example shown, the fluid guiding elements 84, 84′ are configured from a material with good thermal conductivity, for example aluminum, and are attached directly to the heat dispersion layer 62 of the respective printed circuit board 14, 14′ in a thermally conductive manner.

In the configuration example shown, the fluid guiding element 84, 84′ is formed with a continuous floor plate 86 facing the fluid compartment 80, from which projections 88 extend towards the printed circuit board 14, 14′, so that fluid-guiding conduits 90 are formed between adjacent projections. The flow guidance is selected in such a way that, for example, the inlet to the fluid heater 1 is in fluid connection with the conduits 90, so that the flow in the conduits 90—as indicated in FIG. 8—takes place away from the viewer and is then diverted via suitable redirection elements, not shown, so that the flow in the fluid compartment 80 takes place towards the viewer. Of course, other flow guidance is also possible. As explained, the heat Q to be transferred to the fluid is transferred in the direction of the arrow from the printed circuit board 14, 14′ via the respective fluid guiding element 84, 84′ to the fluid contained in the fluid compartment 80.

As already explained in connection with FIG. 7, the printed circuit boards 14, 14′ may also be installed rotated by 180°, so that the fluid guiding elements 84, 84′ are arranged facing the respective clearance 85 or 87 and these then form corresponding fluid spaces, while the central space 80 is the electronics compartment which is sealed off from the fluid spaces.

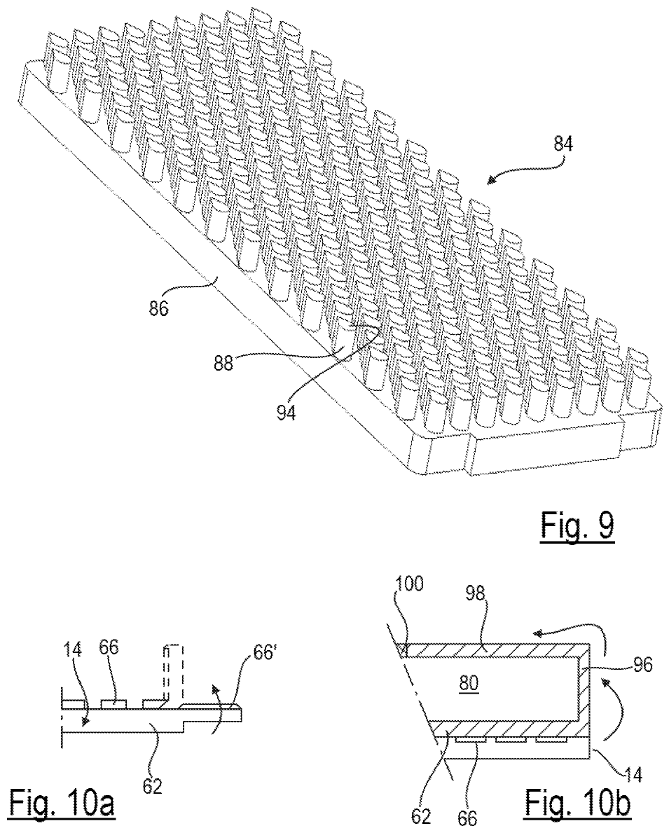

FIG. 9 shows a concrete configuration example of a fluid guiding element 84. As explained, this has a floor plate 86 from which the projections 88 extend. In the configuration example shown, each of these projections has an approximately drop-shaped cross-section 94 that optimizes the flow around it. The fluid guiding element 84 shown in FIG. 9 is made of an aluminum alloy, for example by die casting or extrusion.

As explained above, the projections 88 rest with their drop-shaped end faces on the heat dispersion layer 62 of the respective printed circuit board 14, 14′, wherein a sealing arrangement is preferably selected so that a defined flow is ensured within the conduits 90. However, a certain amount of leakage is in principle unproblematic. In this configuration example, too, the sealing of the fluid compartment 80 with respect to the free clearances 85, 87 and the exterior space 28 is affected by suitable sealing elements 76, 78.

As explained, a distinctive feature according to the application is that, on the one hand, the printed circuit boards 14, preferably IMS printed circuit boards 14, 14′ are configured as heating elements and, on the other hand, bound a part of a fluid compartment receiving the heating fluid. Further embodiments of this concept are explained with reference to FIGS. 10a, 10b.

FIG. 10a shows a variant in which the heat dispersion layer 62 is slightly recessed in edge areas of a printed circuit board 14 so that this recessed area, as indicated by dashed lines in FIG. 10a, can be bent upwards in the direction of the side receiving the conducting path 66 to form terminal lugs or other functional elements. This bending is preferably performed partially only in those areas in which such functional elements, for example terminal lugs, have to be farmed. In the latter case, a conducting-path terminal portion 66′ may extend into the area cut free or limited in accordance with the terminal lug to be formed, which is bent in a subsequent operation to form the terminal lug.

In a further embodiment of the application, a heating line may also be formed completely or in sections in the bent region, wherein contact is then preferably made via the conducting path 66. In such a configuration example, the heating line is thus also formed in the narrower bent sidewalls of the fluid channel. Of course, in such a configuration example, contact may also be made via contact tabs bent out of this bent sidewall, in the area of which a respective conducting-path terminal portion (66′) then ends.

In FIG. 10b, this concept is taken further in that the weakened edge areas of the heat dispersion layer 62 have substantially larger dimensions, so that by bending them twice by 90°, sidewalls 96 and top walls 98, 100 are formed, which then together form at least sections of the circumferential walls of the fluid compartment 80. In such a configuration example, only a printed circuit board 14 would then be configured with a heating circuit 24, 26 according to the application. In this configuration example, the described bends form the circumference of a fluid channel at least in sections. Of course, it is also possible to form an open structure, for example by bending sidewalls 96 and then configuring the top wall as a special component. As explained above, conducting-path portions or conducting-path terminal portions may also extend into the bent areas to then allow contacting with other components.

The IMS printed circuit boards may also be configured with multiple layers, so that conducting-path layers are formed, separated by insulation layers, and lying one on top of the other, which then each form part of a heating line/heating circuit and/or the control or power electronics. For example, a passive sensor element may be integrated, wherein one conducting-path layer is configured for power distribution and the other conducting-path layer is configured essentially as a heating line. In principle, however, several layers may also be formed as a heating line, wherein the respective heating power is adapted by varying the cross-section, in particular the conducting path thickness d.

In principle, the fluid compartment 80 in such variants may also be bounded on the one hand by a single layer printed circuit board and on the other hand by a multilayer printed circuit board with a heating or current distribution function.

Disclosed are a printed circuit board with a heating line formed from conducting paths and a heater implemented with such a printed circuit board.

### LIST OF REFERENCE SYMBOLS

1 fluid heater
2 housing
4 center part
6 upper side of lid
8 lower side of lid
10 fluid connection
12 fluid connection
14 printed circuit board
16 low-voltage plug
18 high-voltage plug
20 pressure-balancing element
22 electronics compartment
24 heating circuit
26 heating circuit
28 exterior space
30 sealing contour
32 thread hole
34 terminal lug
36 terminal lug
38 terminal lug
40 terminal lug
42 switch element
44 switch element
46 connector
48 connector
50 connector
52 connector
53 connector
54 electronic component
56 electronic component
58 heating line
60 heating line
62 heat dispersion layer
64 insulating layer
66 conducting path
66′ conducting-path terminal portion
68 solder resist
70 conducting-path portion
72 conducting-path portion
74 redirection
76 sealing element
78 sealing element
80 fluid compartment
82 temperature sensor
84 fluid guiding element
85 clearance
86 floor plate
87 clearance
88 projection
90 conduit
94 cross-section
96 sidewall
98 top wall
100 top wall

1. A printed circuit board comprising:
at least one conducting path shaped via a subtractive method;
at least one heating line formed by the at least one conducting path and designed to have a predetermined heating power for heating a fluid; and
a heat dispersion layer designed for transferring heat to the fluid.

2. The printed circuit board according to claim 1, having a control circuit and/or power electronics which is in operative connection with the at least one heating line or to which a further conducting path is assigned.

3. The printed circuit board according to claim 1, whereby the at least one heating line is formed by conducting paths, a cross-section, length and material of which are designed according to a heating resistance required for the heating power.

4. The printed circuit board according to claim 1, whereby a fluid guiding element is formed adjacent to the heat dispersion layer.

5. The printed circuit board according to claim 1, whereby a plurality of heating lines are formed thereon.

6. The printed circuit board according to claim 1, whereby the printed circuit board is formed in multiple layers and whereby at least one heating line and/or a circuit forming a control circuit or power electronics are provided in each layer.

7. The printed circuit board according to claim 1, whereby the at least one heating line is formed by at least one meander-shaped or bifilar conducting path.

8. The printed circuit board according to claim 1, whereby it is an IMS-printed circuit board.

9. The printed circuit board according to claim 8, whereby functional elements are formed by bending tabs or edge portions of the printed circuit board, whereby at least the conducting path or a conducting-path terminal portion for forming a contact tab or a heating line/heating line portion is led into the bent region.

10. A heater comprising a heating element adapted to heat a fluid flowing through or contained in a fluid compartment, wherein at least one printed circuit board according to claim 1 is provided.

11. The heater according to claim 10, whereby the printed circuit board bounds the fluid compartment in sections.
